(19) United States
(12) Patent Application Publication
(10) Pub. No.: US 2008/0197872 A1
(43) Pub. Date: Aug. 21, 2008

(54) SEMICONDUCTOR CHIP, MULTI-CHIP SEMICONDUCTOR DEVICE, INSPECTION METHOD OF THE SAME, AND ELECTRIC APPLIANCE INTEGRATING THE SAME

(76) Inventor: Makoto Matsushima, Hyogo (JP)

Correspondence Address: DICKSTEIN SHAPIRO LLP, 1825 EYE STREET NW, Washington, DC, 20006-5403, US

(21) Appl. No.: 12/014,472

(22) Filed: Jan. 15, 2008

(30) Foreign Application Priority Data
Feb. 20, 2007 (JP) 2007-039450

(51) Int. Cl. G01R 31/27; H01L 23/482

(52) U.S. Cl. 324/765; 257/734; 257/E23.015

(57) ABSTRACT

A disclosed semiconductor chip includes a first connection pad adapted to input an input signal; and a second connection pad adapted to selectively output, according to a test mode signal input to the semiconductor chip, one of the input signal and an output signal from the semiconductor chip.

### BACKGROUND OF THE INVENTION

1. Field of the Invention

The present invention relates to a semiconductor chip and a multi-chip semiconductor device that integrates plural of the semiconductor chips in one package. Specifically, the present invention relates to a multi-chip semiconductor device that enables independent inspection of each semiconductor chip integrated in the multi-chip semiconductor device and inspection of interchip connections between the plural semiconductor chips, a method of inspecting such a multi-chip semiconductor device, and an electric appliance integrating the multi-chip semiconductor device.

2. Description of the Related Art

As an LSI package becomes thinner and more miniaturized while containing more semiconductor chips and more terminals, multi-chip packaging (MCP) that enables plural semiconductor chips to be integrated in one package has drawn more attention than conventional packaging that integrates one semiconductor chip in one package, and has been shifted to the mass-production phase.

When plural semiconductor chips are integrated in one package, there are typically two configurations. In a first configuration, the semiconductor chips are stacked one on one, as shown in FIG. 1, while the semiconductor chips are arranged side by side on the same surface in a second configuration. The stacking configuration shown in FIG. 1 is now widely employed due to its advantage of decreased packaging area.

In FIGS. 1 and 2, a reference numeral 10 represents a semiconductor device; 11 represents a first semiconductor chip; 12 represents a second semiconductor chip; 14A and 14B represent external terminals; 15A through 15D represent connection pads; 16A and 16B represent external terminal connection pads; 17A and 17B are connecting wires; 18 represents an interchip wire; and 19 represents molded encapsulation resin. These reference numerals are given to the same or corresponding elements and components in other drawings (FIGS. 4 through 6).

Even if either one of the two configurations is employed, the semiconductor chips have to be mutually connected in the package anyway. Namely, the first semiconductor chip 11 and the second semiconductor chip 12 have not only the connection pads 15A, 15D that are electrically connected to the external terminals 14A, 14B through the connection pads 16A, 16B and the connecting wires 17A, 17B, respectively, but also the connection pads 15B, 15C that connect the first semiconductor chip 11 with the second semiconductor chip 12 through the interchip wire 18. In other words, the connection pads 15B, 15C are only connected to each other but not connected to any external terminals 14X (X=A through Z).

In order to inspect and determine if the connection pads 15B, 15C are securely connected to each other in such a multi-chip package, a function test in which a signal is input to the semiconductor device 10 from one of the external terminals 14X and an output signal corresponding to the input signal is detected from another external terminal 14Y needs to be carried out. However, it takes a long time to inspect all the connections between the connection pads connected by the interchip wires 18, thereby increasing inspection costs.

In addition, there is a problem in that the plural semiconductor chips 11, 12 packaged in the LSI package cannot be individually inspected.

FIG. 3 is a schematic diagram of a multi-chip semiconductor device disclosed in Japanese Laid-Open Patent Application No. 2005-148026 (Patent Document 1).

Such a conventional multi-chip semiconductor device shown in FIG. 3 integrates LSI chips A, B including selectors A, B, respectively.

The LSI chip A includes connection pads in1, in2 for inputting signals, a connection pad TESTA for inputting a control signal, a connection pad out1 for outputting a signal, and connection pads SA1, SA2 connected to output terminals of the selector A.

Similarly, the LSI chip B includes connection pads in1, in2 for inputting signals, a connection pad TESTB for inputting a control signal, a connection pad out2 for outputting a signal, and connection pads SB1, SB2 connected to output terminals of the selector B.

The LSI package has plural external test terminals in addition to external terminals to be used for usual operations of the semiconductor device. The external test terminals are, for example, an external terminal TEST for inputting a control signal to the selectors A, B, input terminals INA, INB, TinA, TinB, and output terminals OUTA, OUTB, ToutA, ToutB, as shown in FIG. 3.

The selector A has a signal input terminal connected to a terminal out2 of the LSI chip A, a control signal input terminal connected to the connection pad TESTA of the LSI chip A, and data output terminals connected respectively to the connection pads SA1, SA2. The selector A is composed of, for example, two three-state buffers whose input terminals are connected in common.

In the semiconductor device, when the control signal is not input to the control signal input terminal TESTA, the connection pad SA1 connected to the external terminal ToutA is in a high-impedance state. On the other hand, when the control signal is input to the control signal input terminal TESTA, the connection pad SA2 connected to the connection pad in1 of the LSI chip B is in a high-impedance state.

Similar to the selector A, the selector B is composed of two three-state buffers whose input terminals are connected in common. When the control signal is not input to the control signal input terminal TESTB, the connection pad SB1 connected to the external terminal ToutB is in a high-impedance state. On the other hand, when the control signal is input to the control signal input terminal TESTB, the connection pad SB2 connected to the connection pad in2 of the LSI chip A is in a high-impedance state.

As explained in reference to FIG. 3, the LSI chip A is provided with the connection pad TESTA to be exclusively used for testing, and the LSI chip B is provided with the connection pad TESTB to be exclusively used for testing in the multi-chip semiconductor device disclosed in the patent reference 1. By inputting the control signal to the connection pad TESTA (TESTB) of the LSI chip A (B), the control signal is input to the control signal input terminal of the selector A (B) and then the connection pad SA2 (SB2) connected to the input terminal in1 (in 2) of the other LSI chip B (A) is maintained in a high-impedance state. In such a manner, the LSI chips A, B can be individually inspected. By the way, the external test terminals for testing are located where the terminals to be used for the usual operations are not formed on the LSI package.

[Patent Document 1] Japanese Laid-Open Patent Application No. 2005-148026.

The conventional multi-chip semiconductor device requires the external test terminals for testing the LSI chips to be integrated in the device. For example, the semiconductor device in the described example has the external test terminals INA, ToutA, TinA for the LSI chip A, and the external terminals INB, ToutB, TinB for the LSI chip B.

The number of the external terminals formed on the package is a significant factor in determining the size of the package. Namely, as the number of the external terminals is increased, the size of the package becomes larger. In addition, this may increase production costs. Moreover, an electrical appliance in which a large semiconductor device is to be implemented needs more space for the semiconductor device, which makes the appliance larger. Therefore, it is preferable that the number of the external terminals be as small as possible.

Furthermore, it is not very easy to inspect electrical connections between the semiconductor chips, for example, the electrical connection between the connection pad SA2 and the connection pad in1 of the LSI chip B, in the described example. Therefore, another inspection method, for example, X-ray analysis, needs to be additionally performed, thereby increasing production costs as a whole.

The present invention has been made in view of the above, and is directed to a multi-chip semiconductor device that enables inspection of electrical connections between the semiconductor chips and inspection of the individual semiconductor chips built into the semiconductor device, and can avoid an increased number of external terminals. In addition, the present invention is directed to an inspection method of such a semiconductor device, and an electric appliance that has such a semiconductor device built-in.

### SUMMARY OF THE INVENTION

A first aspect of the present invention provides a semiconductor chip comprising a first connection pad adapted to input an input signal; and a second connection pad adapted to selectively output, according to a test mode signal input to the semiconductor chip, one of the input signal and an output signal from the semiconductor chip.

A second aspect of the present invention provides a semiconductor chip according to the first aspect, further comprising a switching circuit. The switching circuit includes a first input terminal connected to the first connection pad so as to input the input signal; a second input terminal adapted to input the output signal; a control terminal adapted to input the test mode signal; and an output terminal connected to the second connection pad so as to selectively output, according to the test mode signal, one of the input signal and the output signal.

A third aspect of the present invention provides a semiconductor device comprising plural semiconductor chips, an external input terminal and an external input terminal. Each of the plural semiconductor chips include a first connection pad adapted to input an input signal, and a second connection pad adapted to selectively output, according to a test mode signal input to the semiconductor chip, one of the input signal and an output signal from the semiconductor chip. The external input terminal is connected to the first connection pad of one of the plural semiconductor chips. The external output terminal is connected to the second connection pad of another of the plural semiconductor chips. In the semiconductor device, a connection between two semiconductor chips of the plural semiconductor chips, the two semiconductor chips being to be connected to each other, is made through the second connection pad of one of the two semiconductor chips and the first connection pad of the other of the two semiconductor chips.

A fourth aspect of the present invention provides a semiconductor device, according to the third aspect, in which the first and the second connection pads that made the connection between the two semiconductor chips are not connected to an external terminal. Since the external terminals connected to the first connection pad and the second connection pad that connect the two semiconductor chips are not required, there is no need for additional room for the external terminals, thereby down-sizing the semiconductor device.

A fifth aspect of the present invention provides a semiconductor device, according to the third aspect or the fourth aspect, wherein each of the plural semiconductor chips comprises a switching circuit. The switching circuit includes a first input terminal connected to the first connection pad so as to input the input signal; a second input terminal adapted to input the output signal; a control terminal adapted to input the test mode signal; and an output terminal connected to the second connection pad so as to selectively output, according to the test mode signal, one of the input signal and the output signal.

A sixth aspect of the present invention provides a semiconductor device, according to any one of the third through the fifth aspects, wherein the first connection pad is further connected to an inner electric circuit so as to provide the inner electric circuit with the input signal.

A seventh aspect of the present invention provides a method of inspecting a semiconductor device according to any one of the third through the sixth aspects. The inspection method includes steps of allowing all the plural semiconductor chips to output the output signals from the corresponding second connection pads; applying a predetermined signal to the external input terminal; and detecting a signal from the external output terminal so as to inspect and determine if the semiconductor device operates normally.

An eighth aspect of the present invention provides a method of inspecting a semiconductor device according to the third through the sixth aspects. The method includes steps of allowing one of the plural semiconductor chips to output the output signal from the second connection pad of the semiconductor chip, and allowing the remaining semiconductor chips to output the input signals from the corresponding second connection pads; applying a predetermined signal to the external input terminal; and detecting a signal from the external output terminal so as to inspect and determine if the semiconductor chip operates normally.

A ninth aspect of the present invention provides a method of inspecting a semiconductor device according to the third through the sixth aspects. The method includes steps of allowing all the plural semiconductor chips to output the input signals from the corresponding second connection pads; applying a predetermined signal to the external input terminal; and detecting a signal from the external output terminal so as to inspect and determine if the interchip connections are properly made.

A tenth aspect of the present invention provides an electric appliance comprising a semiconductor device according to any one of the third through the sixth aspects.

According to the above semiconductor chips, since a first connection pad can input an input signal and a second connection pad can selectively output, according to a test mode signal input to the semiconductor chip, one of the input signal and an output signal from the semiconductor chip, when plural of the semiconductor chips are integrated into a package, the semiconductor chips can be independently inspected and the interchip connections can be inspected by selecting a combination of the test mode signals input to the corresponding semiconductor chips.

In addition, it becomes unnecessary to connect the connection pads to be used for the interchip connection to the external terminals for the purpose of inspecting the interchip connection. In addition, such connection pads can be used as input/output terminals for normal operations and as test terminals. Therefore, the need for additional external terminals is eliminated, thereby avoiding an increased number of the external terminals. As a result, the multi-chip semiconductor device and thus the electric appliances employing the semiconductor device can be down-sized.

Moreover, since inspection of the interchip connections and each semiconductor chip becomes possible without any complicated functions according to an embodiment of the present invention, an inspection method can be simplified, inspection time can be shortened, and production costs can be reduced.

### BRIEF DESCRIPTION OF THE DRAWINGS

Other objects, features and advantages of the present invention will become more apparent from the following detailed description when read in conjunction with the accompanying drawings, in which:

FIG. 1 is a schematic diagram of a related-art multi-chip semiconductor device;

FIG. 2 is a schematic diagram of another related-art multi-chip semiconductor device;

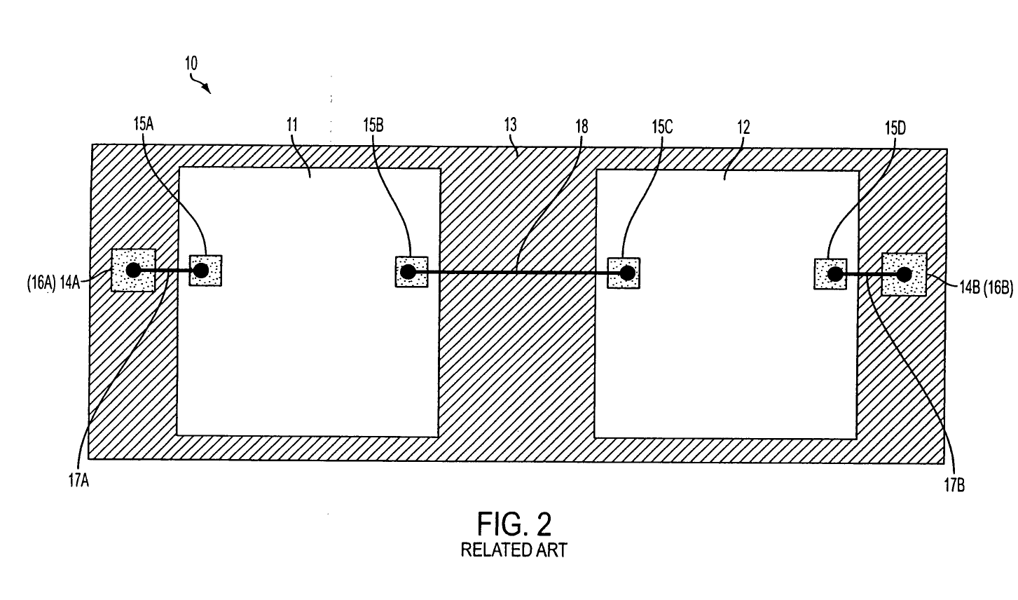

FIG. 3 is a circuit diagram of yet another related-art multi-chip semiconductor device;

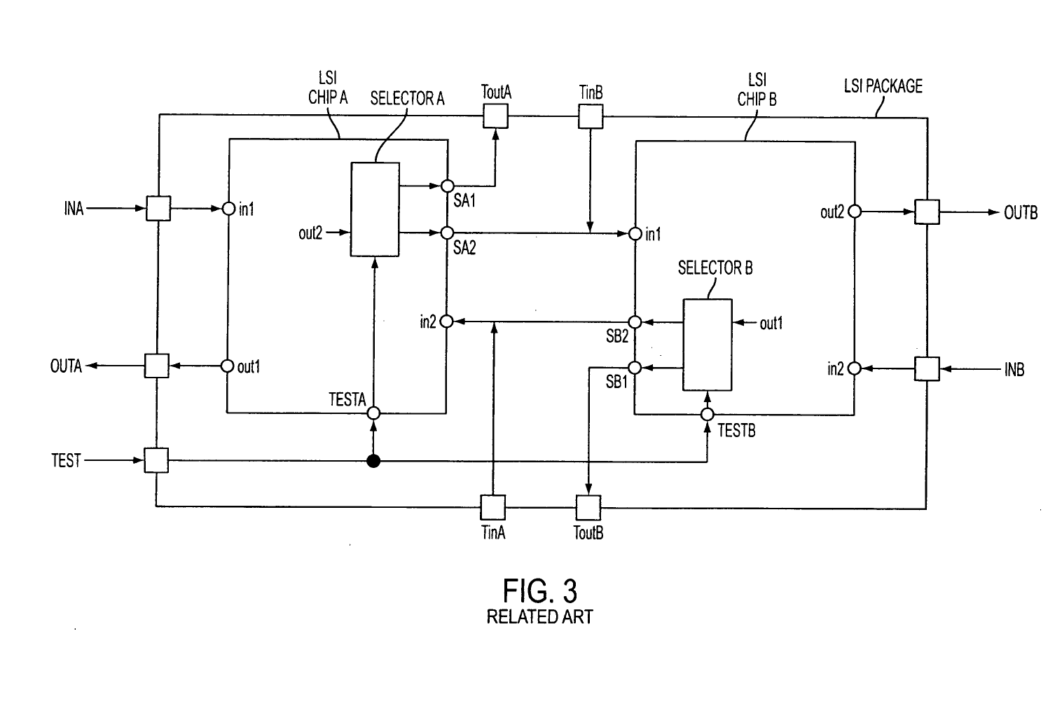

FIG. 4 is a schematic diagram of a multi-chip semiconductor device according to a first embodiment of the present invention;

FIG. 5 is a schematic diagram of a multi-chip semiconductor device according to a second embodiment of the present invention; and

FIG. 6 is a schematic diagram of a multi-chip semiconductor device according to a third embodiment of the present invention.

### DETAILED DESCRIPTION OF THE PREFERRED EMBODIMENTS

Referring to the accompanying drawings, exemplary embodiments of the present invention will be described. In all the drawings, the same or corresponding reference marks are given to the same or corresponding members or components, as necessary. It is to be noted that the drawings are illustrative of the invention, and there is no intention to indicate scale or relative proportions among the members or components.

### First Embodiment

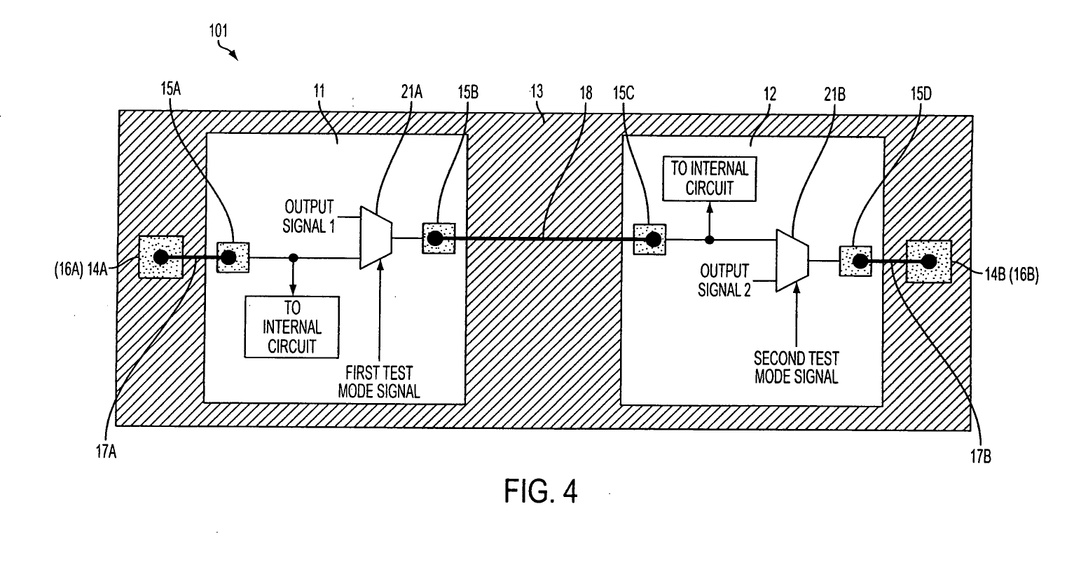

FIG. 4 is a schematic diagram of a multi-chip semiconductor device according to a first embodiment of the present invention. In FIG. 4, two semiconductor chips are arranged side by side for simplicity of explanations. However, the semiconductor chips may be stacked one on one in other embodiments.

A semiconductor device 101 has a first semiconductor chip 11 and a second semiconductor chip 12. The first semiconductor chip 11 has a switching circuit 21A. The switching circuit 21A has a first input terminal that inputs a signal applied to a first connection pad 15A, a second input terminal that inputs an output signal 1 from the first semiconductor chip 11, and an output terminal connected to a second connection pad 15B.

Similarly, the second semiconductor chip 12 has a switching circuit 21B. The switching circuit 21B has a first input terminal that inputs a signal applied to a first connection pad 15C, a second input terminal that inputs an output signal 2 from the second semiconductor chip 12, and an output terminal connected to a second connection pad 15D.

In addition, the switching circuit 21A has a control input terminal to which a first test mode signal may be applied. Similarly, the switching circuit 21B has a control input terminal to which a second test mode signal may be applied.

When the first test mode signal is applied to the control input terminal of the switching circuit 21A, the switching circuit 21A outputs to the second connection pad 15B a signal from the first connection pad 15A. In addition, when the first test mode signal is not applied to the control input terminal of the switching circuit 21A, the switching circuit 21A outputs to the second connection pad 15B the output signal 1 from the first semiconductor chip 11.

Similarly, when the second test mode signal is applied to the control input terminal of the switching circuit 21B, the switching circuit 21B outputs to the second connection pad 15D a signal from the first connection pad 15C. In addition, when the first test mode signal is not applied to the control input terminal of the switching circuit 21A, the switching circuit 21A outputs to the second connection pad 15D the output signal 2 from the second semiconductor chip 12.

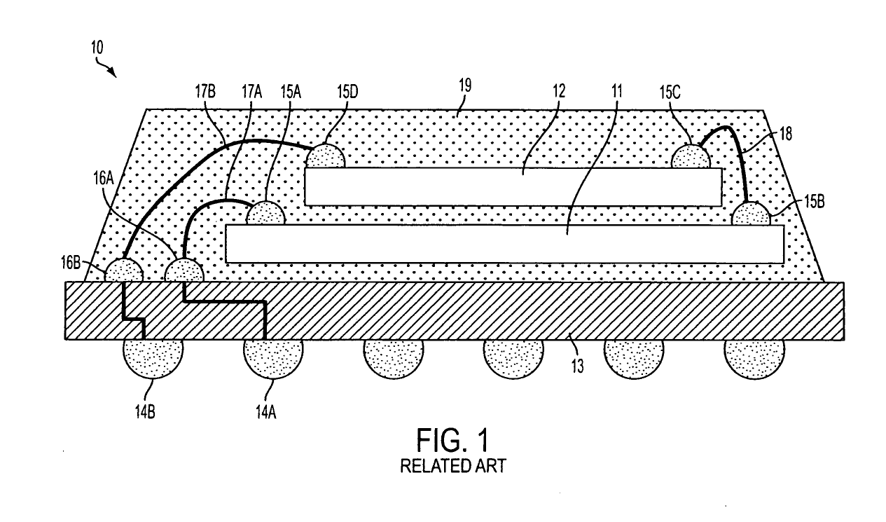

The first connection pad 15A of the semiconductor chip 11 is connected to an external terminal 14A via a connecting wire 17A and an external terminal connection pad 16A of a rewiring substrate 13. In addition, the first connection pad 15A is connected to an internal circuit of the first semiconductor chip 11 and the first input terminal of the switching circuit 21A. (Refer to FIG. 1 for an example of the configuration of the external terminal 14A and the pad 16A.)

The second connection pad 15B of the first semiconductor chip 11 is connected to the first connection pad 15C of the second semiconductor chip 12 via an interchip wire 18.

The first connection pad 15C of the second semiconductor chip 12 is connected to the first input terminal of the switching circuit 21B. The second connection pad 15D of the second semiconductor chip 12 is connected to an external terminal 14B via a connecting wire 17B and an external terminal connection pad 16B of the rewiring substrate 13. (Refer to FIG. 1 for an example of the configuration of the external terminal 14B and the pad 16B.)

### (Normal Operation)

In order to allow the semiconductor device 101 to operate normally, the first test mode signal is not input to the control input terminal of the switching circuit 21A and the second test mode signal is not input to the control input terminal of the switching circuit 21B. In this case, the output signal 1 from the first semiconductor chip 11 is output to the second connection pad 15B of the first semiconductor chip 11, and input to the first connection pad 15C of the second semiconductor chip 12 and thus to the internal circuit of the second semiconductor chip 12. In addition, the output signal 2 from the second semiconductor chip 12 is output to the second connection pad 15D of the second semiconductor chip 12.

In such a manner, the first and the second semiconductor chips 11, 12 can cooperatively operate and the semiconductor device 101 can be inspected as a whole using the external terminals 14A, 14B.

### (Inspection of the First Semiconductor Chip)

When only the first semiconductor chip 11 is inspected, the second test mode signal is input to the control input terminal of the switching circuit 21B of the second semiconductor chip 12, whereas the first test mode signal is not input to the control input terminal of the switching circuit 21A of the first semiconductor chip 11.

In this case, the output signal 1 from the semiconductor chip 11 can be observed through the second connection pad 15B, the interchip wire 18, the first connection pad 15C, the switching circuit 21B, the second connection pad 15D, the connecting wire 17B, the external terminal connection pad 16B, and the external terminal 14B.

In addition, since a signal applied to the external terminal 14A can be applied to the internal circuit of the first semiconductor chip 11, the semiconductor chip 11 can be inspected by using the external terminals 14A, 14B, independent of the second semiconductor chip 12.

### (Inspection of the Second Semiconductor Chip)

When only the second semiconductor chip 12 is inspected, the first test mode signal is input to the control input terminal of the switching circuit 21A of the first semiconductor chip 11, whereas the second test mode signal is not input to the control input terminal of the switching circuit 21B of the second semiconductor chip 12.

In this case, the signal applied to the external terminal 14A is applied to the first connection pad 15C of the second semiconductor chip 12 via the external terminal connection pad 16A, the connecting wire 17A, the first connection pad 15A, the switching circuit 21A, the second connection pad 15B, and the interchip wire 18. Namely, it becomes possible to apply an arbitrary input signal to the second semiconductor chip 12, passing through the first semiconductor chip 11.

In addition, the output signal 2 from the second semiconductor chip 12 is output from the switching circuit 21B, and can be observed through the second connection pad 15D, the connecting wire 17B, the external terminal connection pad 16B, and the external terminal 14B. Therefore, the second semiconductor chip 12 can be inspected by using the external terminals 14A, 14B, independent of the first semiconductor chip 11.

### (Inspection of the Interchip Wire)

When the interchip wire 18 connecting the second connection pad 15B of the first semiconductor chip 11 and the first connection pad 15C of the second semiconductor chip 12 is inspected, the first test mode signal is input to the switching circuit 21A and the second test mode signal is input to the switching circuit 21B.

In this case, since the switching circuit 21A outputs the signal applied to the first connection pad 15A of the first semiconductor chip 11 and the switching circuit 21B outputs the signal applied to the first connection pad 15C of the second semiconductor chip 12, the signal applied to the external terminal 14A is output to the external terminal 14B through the switching circuit 21A of the first semiconductor chip 11, the interchip wire 18, and the switching circuit 21B of the second semiconductor chip 12.

Therefore, the interchip wire 18 can be readily inspected by only checking whether the signal applied to the external terminal 14A appears on the external terminal 14B.

By the way, since the first connection pad 15A of the semiconductor chip 11 is connected to the inner circuit of the first semiconductor chip 11 as well as the first input terminal of the switching circuit 21A, and the first connection pad 15C of the second semiconductor chip 12 is connected to the inner circuit of the second semiconductor chip 12 as well as the first input terminal of the switching circuit 21B, the first connection pads 15A, 15C can be inspected at the same time when either one of the first semiconductor chip 11, the second semiconductor chip 12, and the interchip wire 18 is inspected. Namely, test terminals for inspecting the first connection pads 15A, 15C are not necessary, which can avoid an increased number of test terminals and down-size the multi-chip semiconductor device 101.

### Second Embodiment

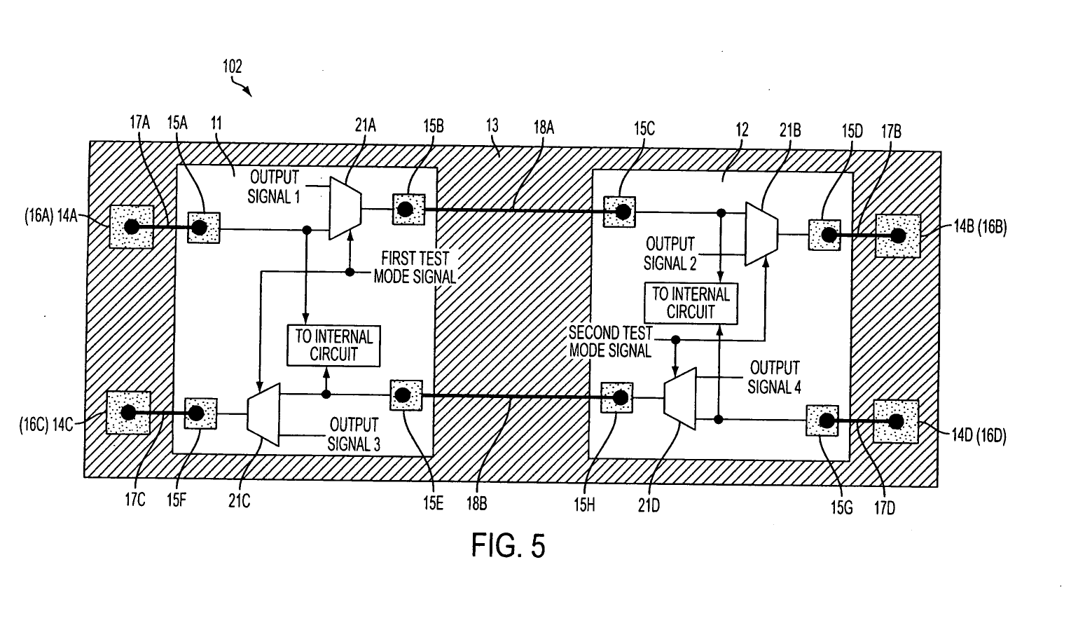

FIG. 5 is a schematic view of a multi-chip semiconductor device 102 according to a second embodiment of the present invention. In the same manner as FIG. 4, while two semiconductor chips are arranged side by side in FIG. 5 for simplicity of explanations, the semiconductor chips may be stacked one on one in other embodiments.

The semiconductor device 102 according to the second embodiment is different from the semiconductor device 101 according to the first embodiment in that the first semiconductor chip 11 has an additional switching circuit 21C and the second semiconductor chip 12 has an additional switching circuit 21D.

The switching circuit 21C added to the first semiconductor chip 11 has a first input terminal connected to a first connection pad 15E formed on the first semiconductor chip 11, and a second input terminal that inputs an output signal 3 from the first semiconductor chip 11. In addition, the switching circuit 21C has an output terminal connected to a second connection pad 15F which in turn is connected to an external terminal 14C via a connecting wire 17C and an external terminal connection pad 16C of the rewiring substrate 13. Moreover, the switching circuit 21c has a control input terminal for inputting the first test mode signal. By the way, the first connection pad 15E is also connected to the inner circuit of the first semiconductor chip 11.

On the other hand, the switching circuit 21D added to the second semiconductor chip 12 has a first input terminal connected to a first connection pad 15G formed on the second semiconductor chip 12, and a second input terminal that inputs an output signal 4 from the second semiconductor chip 12. In addition, the switching circuit 21D has an output terminal connected to a second connection pad 15H that is in turn connected to the first connection pad 15E of the first semiconductor chip 11 via an interchip wire 18B.

The first connection pad 15G is also connected to the inner circuit of the second semiconductor chip 12, and an external terminal 14D via a connecting wire 17D and an external terminal connection pad 16D of the rewiring substrate 13.

### (Normal Operation)

In order to allow the semiconductor device 102 to normally operate, no test mode signals are input to the control input terminals of the switching circuits 21A through 21D. In this case, since the output terminals of the switching circuits 21A through 21D output the output signals 1 through 4, respectively, the first semiconductor chips 11, 12 can cooperatively operate so as to input/output signals. Therefore, the semiconductor device 102 as a whole can be inspected.

### (Inspection of the First Semiconductor Chip)

When only the first semiconductor chip 11 is inspected, the second test mode signals are input to the switching circuits 21B, 21D of the second semiconductor chip 12, while the first test mode signals are not input to the switching circuits 21A, 21C of the first semiconductor chip 11.

In this case, the output signal 1 from the semiconductor chip 11 can be observed through the second connection pad 15B, the interchip wire 18A, the first connection pad 15C, the switching circuit 21B, the second connection pad 15D, the connecting wire 17B, the external terminal connection pad 16B, and the external terminal 14B, in the same manner described for the first embodiment of the present invention.

In addition, the output signal 3 is output from the switching circuit 21C to the second connection pad 15F. Moreover, a signal applied to the external terminal 14D is applied to the first connection pad 15E through the external terminal connection pad 16D, the connecting wire 17D, the first connection pad 15G, the switching circuit 21D, the second connection pad 15H, and the interchip wire 18B. Therefore, the first semiconductor chip 11 can be inspected independent of the second semiconductor chip 12.

### (Inspection of the Second Semiconductor Chip)

When only the second semiconductor chip 12 is inspected, the first test mode signals are input to the control input terminals of the switching circuits 21A, 21C of the first semiconductor chip 11, while the second test signals are not input to the control input terminals of the switching circuits 21B, 21D of the second semiconductor chip 12. Due to this, the second semiconductor chip 12 can be inspected independent of the first semiconductor chip 11, in a similar manner when the first semiconductor chip 11 is inspected.

### (Inspection of the Interchip Wires)

When the interchip wires 18A, 18B that electrically connect the first semiconductor chip 11 and the second semiconductor chip 12 are inspected, the first test mode signals are input to the switching circuits 21A, 21C of the first semiconductor chip 11, and the second test mode signals are input to the switching circuits 21B, 21D of the second semiconductor chip 12.

In this case, the switching circuits 21A, 21C of the first semiconductor chip 11 output the signals applied to the first connection pads 15A, 15E, respectively, and the switching circuits 21B, 21D of the second semiconductor chip 12 output the signals applied to the first connection pads 15C, 15G, respectively. Therefore, when the interchip wires 18A, 18B are connected without failures, the signal applied to the external terminal 14A is output to the external terminal 14B, and the signal applied to the external terminal 14D is output to the external terminal 14C. In such a manner, the interchip wires 18A, 18B can be readily inspected.

In addition, the first connection pads 15A, 15E of the first semiconductor chip 11 are connected to the inner circuit of the first semiconductor chip 11 and the corresponding switching circuits 21A, 21C. Therefore, the first connection pads 15A, 15E can be inspected at the same time when the first semiconductor chip 11, the second semiconductor chip 12, or the interchip wires 18A, 18B are inspected.

Similarly, the first connection pads 15C, 15G of the second semiconductor chip 12 are connected to the inner circuit of the first semiconductor chip 12 and the corresponding switching circuits 21B, 21D. Therefore, the first connection pads 15C, 15G can be inspected at the same time when the first semiconductor chip 11, the second semiconductor chip 12, or the interchip wires 18A, 18B are inspected. Namely, there is no need for providing test terminals for inspecting the first connection pads 15A, 15C, 15E, 15G, which can avoid an increased number of the test terminals.

### Third Embodiment

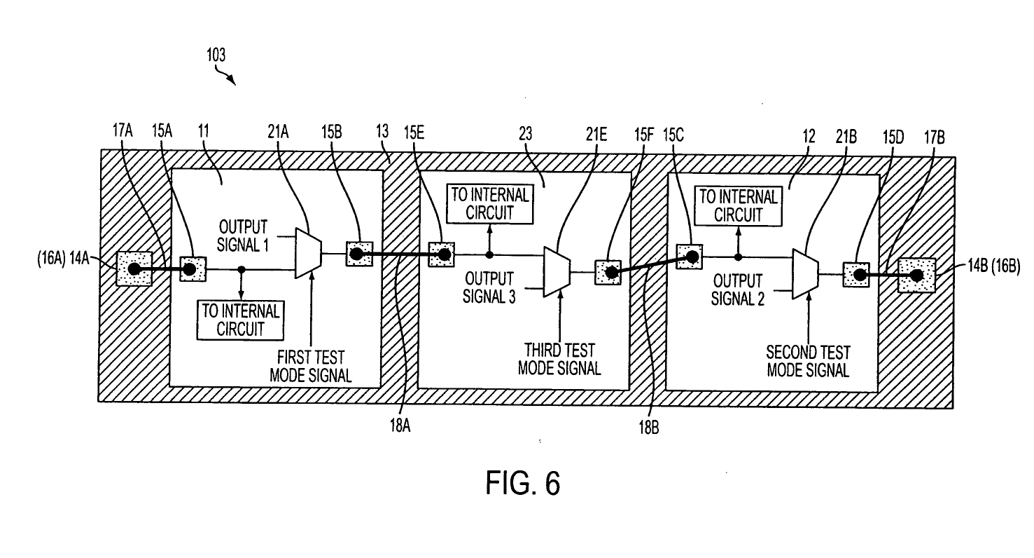

FIG. 6 is a schematic view of a multi-chip semiconductor device 103 according to a third embodiment of the present invention. In the same manner as FIG. 4, while the semiconductor chips are arranged side by side for simplicity of explanations, the semiconductor chips may be stacked one on one in other embodiments.

The semiconductor device 103 according to the third embodiment of the present invention is different from the semiconductor device 101 according to the first embodiment of the present invention in that a third semiconductor chip 23 is added between the first semiconductor chip 11 and the second semiconductor chip 12.

The third semiconductor chip 23 has a switching circuit 21E having substantially the same configuration as the switching circuits 21A through 21D in the first and the second embodiments. Namely, the switching circuit 21E has a first input terminal connected to a first connection pad 15E, a second input terminal that inputs an output signal 3 from the third semiconductor chip 23, an output terminal connected to a second connection pad 15F, and a control input terminal that inputs a third test mode signal, as shown in FIG. 6.

### (Normal Operation)

In order to allow the semiconductor device 103 to normally operate, no test mode signals are input to the control input terminals of the switching circuits 21A, 21B, 21E. In this case, the switching circuit 21A outputs the output signal 1 to the second connection pad 15B of the first semiconductor chip 11, the first connection pad 15E of the third semiconductor chip 23 and thus the inner circuit of the third semiconductor chip 23; the switching circuit 21E outputs the output signal 3 to the second connection pad 15F of the third semiconductor chip 23, the first connection pad 15C of the second semiconductor chip 12 and thus the inner circuit of the second semiconductor chip 12; and the switching circuit 21B outputs the output signal 2 to the second connection pad 15D of the second semiconductor chip 12, the external terminal connection pad 16B and thus the external terminal 14B. In such a manner, the semiconductor chips 11, 12, 23 can cooperatively operate and the semiconductor device 103 as a whole can be inspected using the external terminals 14A, 14B.

### (Inspection of the First Semiconductor Chip)

When only the first semiconductor chip 11 is inspected, the second test mode signal is input to the control input terminal of the switching circuit 21B of the second semiconductor chip 12, and the third test mode signal is input to the control input terminal of the switching circuit 21E of the third semiconductor chip 23, while the first test mode signal is not input to the control input terminal of the switching circuit 21A of the first semiconductor chip 11.

In this case, the output signal 1 from the first semiconductor chip 11 appears on the external terminal 14B through the switching circuit 21E of the third semiconductor chip 23 and the switching circuit 21B of the second semiconductor chip 12. Therefore, only the first semiconductor chip 11 can be inspected independent of the second and the third semiconductor chips 12, 23.

### (Inspection of the Second Semiconductor Chip)

When only the second semiconductor chip 12 is inspected, the first test mode signal is input to the control input terminal of the switching circuit 21A of the first semiconductor chip 11, and the third test mode signal is input to the control input terminal of the switching circuit 21E of the third semiconductor chip 23, while the second test mode signal is not input to the control input terminal of the switching circuit 21B of the second semiconductor chip 12.

In this case, a signal applied to the external terminal 14A can be applied to the first connection pad 15C of the second semiconductor chip 12, passing through the first and the third semiconductor chips 11, 23. In addition, the output signal 2 of the second semiconductor chip 12 is output from the switching circuit 21B to the external terminal 14B through the second connection pad 15D of the second semiconductor chip 12 and the external terminal connection pad 16B. Therefore, only the second semiconductor chip 12 can be inspected independent of the first and the third semiconductor chips 11, 23.

### (Inspection of the Third Semiconductor Chip)

When only the third semiconductor chip 23 is inspected, the first test mode signal is input to the control input terminal of the switching circuit 21A of the first semiconductor chip 11, and the second test mode signal is input to the control input terminal of the switching circuit 21B of the second semiconductor chip 12, while the third test mode signal is not input to the control input terminal of the switching circuit 21E of the third semiconductor chip 23.

In this case, a signal applied to the external terminal 14A can be applied to the first connection pad 15E of the third semiconductor chip 23, passing through the first semiconductor chip 11, and the output signal 3 of the third semiconductor chip 23 is output from the switching circuit 21E to the external terminal 14B through the second semiconductor chip 12. Therefore, only the third semiconductor chip 23 can be inspected independent of the first and the second semiconductor chips 11, 12.

As stated above, any semiconductor chip to be the subject of the inspection can be selected from the plural semiconductor chips 11, 12, 23 only by not applying the test mode signal corresponding to the semiconductor chip concerned while applying the other test mode signals to the other semiconductor chips.

### (Interchip Wire)

When the interchip wires 18A, 18B that connect the corresponding adjacent two semiconductor chips are inspected, the first test mode signal is input to the first switching circuit 21A of the first semiconductor chip 11, the second test mode signal is input to the second switching circuit 21B of the second semiconductor ship 12, and the third test mode signal is input to the third switching circuit 21C of the third semiconductor chip 23.

In this case, since the external terminals 14A, 14B are connected through the first through the third semiconductor chips 11, 12, 23, the interchip wires 18A, 18B can be readily inspected by inputting a signal to the external terminal 14A and observing a corresponding signal appeared on the external terminal 14B.

As is the case with the first and the second embodiments, the first connection pad 15E of the third semiconductor chip 23 is connected to the internal circuit of the third semiconductor chip 23 as well as the first input terminal of the switching circuit 21E. Namely, the connection pad 15E can be used for the normal operations of and inspection for the third semiconductor chip 23.

As described for the first through the third embodiments of the present invention, even when there are the connection pads that are used for connecting the adjacent semiconductor chips and not connected to the external terminals, the interchip wire between the connection pads can be inspected. In addition, any one of the semiconductor chips can be inspected independent of the other semiconductor chips by selecting a combination of the test mode signals to be input to the corresponding switching circuits.

### Fourth Embodiment

In the semiconductor device 103 according to the third embodiment, the third semiconductor chip 23 is provided between the first and the second semiconductor chips 11, 12 of the semiconductor device 101 according to the first embodiment. Similarly, another semiconductor device having a third semiconductor chip between the first and the second semiconductor chips 11, 12 of the semiconductor device 102 according to the second embodiment is conceivable as a fourth embodiment of the present invention. This third semiconductor chip may have substantially the same configuration as the first and the second semiconductor chips 11, 12 of the semiconductor device 102.

By the way, the semiconductor devices integrating up to three semiconductor chips have been described in the above embodiments. However, it is obvious to those skilled in the art that the semiconductor device may have four or more semiconductor chips.

According to the present invention, it is only by selecting a combination of the test mode signals to be input to the corresponding semiconductor chips that each of the semiconductor chips and the connections between the two semiconductor chips connected with each other can be inspected. In addition, the semiconductor device according to the embodiments of the present invention can avoid an increased number of the external terminals for inspection, which is advantageous in down-sizing the semiconductor device and thus an electric appliance that has the semiconductor device integrated.

Although the present invention has been described in conjunction with the foregoing specific embodiments, many alterations and modifications will be apparent to those skilled in the art. Those alterations and modifications are intended to fall within the scope of the invention set forth in accompanying claims.

The present application contains subject matter related to Japanese patent application No. 2007-039450, filed with the Japanese Patent Office on Feb. 20, 2007, the entire contents of which are incorporated herein by reference.

What is claimed is:

1. A semiconductor chip comprising:
a first connection pad adapted to input an input signal; and
a second connection pad adapted to selectively output, according to a test mode signal input to the semiconductor chip, one of the input signal and an output signal from the semiconductor chip.

2. The semiconductor chip of claim 1, further comprising a switching circuit including:
a first input terminal connected to the first connection pad so as to input the input signal;
a second input terminal adapted to input the output signal;
a control terminal adapted to input the test mode signal; and
an output terminal connected to the second connection pad so as to selectively output, according to the test mode signal, one of the input signal input from the first input terminal and the output signal input from the second input terminal.

3. A semiconductor device comprising:
plural semiconductor chips, each including
a first connection pad adapted to input an input signal, and
a second connection pad adapted to selectively output, according to a test mode signal input to the semiconductor chip, one of the input signal and an output signal from the semiconductor chip;
an external input terminal connected to the first connection pad of one of the plural semiconductor chips; and
an external output terminal connected to the second connection pad of another of the plural semiconductor chips,
wherein a connection between two semiconductor chips of the plural semiconductor chips, the two semiconductor chips being to be connected to each other, is made through the second connection pad of one of the two semiconductor chips and the first connection pad of the other of the two semiconductor chips.

4. The semiconductor device of claim 3, wherein the first and the second connection pads that made the connection between the two semiconductor chips are not connected to an external terminal.

5. The semiconductor device of claim 3, wherein each of the plural semiconductor chips comprises a switching circuit including:
a first input terminal connected to the first connection pad so as to input the input signal;
a second input terminal adapted to input the output signal;
a control terminal adapted to input the test mode signal; and
an output terminal connected to the second connection pad so as to selectively output, according to the test mode signal, one of the input signal input from the first input terminal and the output signal input from the second input terminal.

6. The semiconductor device of claim 3, wherein the first connection pad is further connected to an inner electric circuit of the semiconductor chip as to provide the inner electric circuit with the input signal.

7. A method of inspecting a semiconductor device of claim 3, the method comprising steps of:
allowing the plural semiconductors to output the output signals from the corresponding second connection pads;
applying a predetermined signal to the external input terminal; and
detecting a signal from the external output terminal so as to determine if the semiconductor device operates normally.

8. A method of inspecting a semiconductor device of claim 3, the method comprising steps of:
allowing one of the plural semiconductor chips to output the output signal from the second connection pad of the semiconductor chip, and allowing the remaining semiconductor chips to output the input signals from the corresponding second connection pads;
applying a predetermined signal to the external input terminal connected to the first; and
detecting a signal from the external output terminal so as to determine if the one of the plural semiconductor chip operates normally.

9. A method of inspecting a semiconductor device of claim 3, the method comprising steps of:
allowing all the plural semiconductor chips to output the input signals from the corresponding second connection pads;
applying a predetermined signal to the external input terminal; and
detecting a signal from the external output terminal so as to determine if the connections are properly made.

10. An electric appliance comprising a semiconductor device of claim 3.
